(19) United States
(12) Patent Application Publication
(10) Pub. No.: US 2018/0127880 A1
(43) Pub. Date: May 10, 2018

(54) MICROWAVE PLASMA SOURCE AND MICROWAVE PLASMA PROCESSING APPARATUS

(71) Applicant: Tokyo Electron Limited, Tokyo (JP)

(72) Inventors: Koji Kotani, Yamanashi (JP); Souichi Nishijima, Yamanashi (JP); Toshio Nakanishi, Yamanashi (JP); Cheonsoo Han, Yamanashi (JP)

(21) Appl. No.: 15/798,611

(22) Filed: Oct. 31, 2017

(30) Foreign Application Priority Data
Nov. 9, 2016 (JP) 2016-218574

(51) Int. Cl. C23C 16/511; H01J 37/32; C23C 16/44; C23C 16/34; C23C 16/32

(52) U.S. Cl. CPC C23C 16/511; H01J 37/32229; H01J 37/3222; H01J 2237/3321; C23C 16/345; C23C 16/32; C23C 16/4412

(57) ABSTRACT

Disclosed is a microwave plasma source including a microwave generator that generates microwaves; a waveguide that propagates the microwaves in a TE mode; a microwave converter including a conversion port that converts a vibration mode of the microwaves guided from the waveguide from the TE mode into a TEM mode, and a coaxial waveguide that propagates the microwaves from the conversion port toward the chamber and converts a remaining TE mode component into the TEM mode during the propagation; a planar antenna including a plurality of slots that radiate the microwaves guided to the coaxial waveguide toward the chamber; and a microwave transmitting plate made of a dielectric material that transmits the microwaves radiated from the plurality of slots of the planar antenna to the chamber. A length of the coaxial waveguide is equal to or longer than a wavelength of the microwaves generated from the microwave generator.

### CROSS-REFERENCE TO RELATED APPLICATIONS

This application is based on and claims priority from Japanese Patent Application No. 2016-218574 filed on Nov. 9, 2016 with the Japan Patent Office, the disclosure of which is incorporated herein in its entirety by reference.

### TECHNICAL FIELD

The present disclosure relates to a microwave plasma source and a microwave plasma processing apparatus.

### BACKGROUND

A plasma processing is an indispensable technique for manufacturing semiconductor devices. Recently, however, design rules of semiconductor elements constituting a large scale integrated circuit (LSI) have been increasingly miniaturized due to a demand for high integration and high speed of the LSI, and the size of semiconductor wafers has been increased. Accordingly, it is requested that a plasma processing apparatus cope with such miniaturization and enlargement.

In the related art, a parallel plate type or inductively coupled plasma processing apparatus has been used as a plasma processing apparatus, but it is difficult to perform a uniform and high-speed plasma processing on a large semiconductor wafer.

Therefore, an RLSA (registered trademark) microwave plasma processing apparatus capable of uniformly forming surface wave plasma of high density and low electron temperature has attracted attention (see, e.g., Japanese Patent Laid-Open Publication No. 2000-294550).

In the RLSA (registered trademark) microwave plasma processing apparatus, a planar antenna having a plurality of slots formed in a predetermined pattern is provided in an upper portion of a chamber, and microwaves guided from a microwave generator are guided to the planar antenna via a slow-wave member made of a dielectric material. Then, the microwaves are radiated from the slots of the planar antenna, and transmitted through a top wall of a chamber made of a dielectric into the chamber, which is maintained in vacuum, to generate surface wave plasma in the chamber. Then, by the plasma, the gas introduced into the chamber is turned into plasma to process a workpiece such as, for example, a semiconductor wafer.

In the RLSA (registered trademark) microwave plasma processing apparatus, the microwaves generated in the microwave generator are guided to a mode converter via a waveguide having a circular cross section or a rectangular cross section, and the vibration mode of the microwaves is converted from the TE mode into the TEM mode by the mode converter. Then, the traveling direction of the microwaves is bent by 90° so that the TEM mode microwaves are guided to the planar antenna via a coaxial waveguide having an outer conductor and an inner conductor (see, e.g., International Publication No. 2011/021607). Further, according to International Publication No. 2011/021607, a stub member capable of extending from the outer conductor to the inner conductor of the coaxial waveguide is provided at a lower part of the coaxial waveguide to adjust the electric field in the circumferential direction of the coaxial waveguide, thereby improving the uniformity of the plasma and uniformly performing a processing in the plane of a processing target substrate.

### SUMMARY

According to a first aspect of the present disclosure, there is provided a microwave plasma source that generates microwave plasma by radiating microwaves into a chamber in a microwave plasma processing apparatus for performing a plasma processing in the chamber. The microwave plasma source includes a microwave generator that generates microwaves; a waveguide that propagates the microwaves generated by the microwave generator in a TE mode; a microwave converter including a conversion port that converts a vibration mode of the microwaves guided from the waveguide from the TE mode into a TEM mode, and a coaxial waveguide that propagates the microwaves from the conversion port toward the chamber and converts a remaining TE mode component into the TEM mode during the propagation; a planar antenna including a plurality of slots that radiate the microwaves guided to the coaxial waveguide toward the chamber; and a microwave transmitting plate made of a dielectric material that transmits the microwaves radiated from the plurality of slots of the planar antenna to the chamber. A length of the coaxial waveguide is equal to or longer than a wavelength of the microwaves generated from the microwave generator.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a schematic configuration of a microwave plasma processing apparatus according to an exemplary embodiment of the present disclosure.

FIG. 2 is a cross-sectional view for explaining a height of a coaxial waveguide used in the microwave plasma processing apparatus of FIG. 1.

FIG. 3 is a view illustrating simulation results that represent a relationship between the height (length) of the coaxial waveguide and the electric field uniformity.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Although the non-uniformity of the electric field in the circumferential direction may be corrected to some extent by the stub member, it has been recently required to further enhance the in-plane uniformity of the plasma processing. Thus, the uniformity of the electric field distribution obtained only by the stub member has become insufficient.

Therefore, the present disclosure is to provide a microwave plasma source and a microwave plasma processing apparatus capable of enhancing the uniformity of the plasma processing in the plane of a workpiece with a high electric field uniformity of the microwaves.

According to a first aspect of the present disclosure, there is provided a microwave plasma source that generates microwave plasma by radiating microwaves into a chamber in a microwave plasma processing apparatus for performing a plasma processing in the chamber. The microwave plasma source includes a microwave generator that generates microwaves; a waveguide that propagates the microwaves generated by the microwave generator in a TE mode; a microwave converter including a conversion port that converts a vibration mode of the microwaves guided from the waveguide from the TE mode into a TEM mode, and a coaxial waveguide that propagates the microwaves from the conversion port toward the chamber and converts a remaining TE mode component into the TEM mode during the propagation; a planar antenna including a plurality of slots that radiate the microwaves guided to the coaxial waveguide toward the chamber; and a microwave transmitting plate made of a dielectric material that transmits the microwaves radiated from the plurality of slots of the planar antenna to the chamber. A length of the coaxial waveguide is equal to or longer than a wavelength of the microwaves generated from the microwave generator.

According to a second aspect of the present disclosure, there is provided a microwave plasma processing apparatus including: a chamber in which a workpiece is accommodated; a microwave generator that generates microwaves; a waveguide that propagates the microwaves generated by the microwave generator in a TE mode; a microwave converter including a conversion port that converts a vibration mode of the microwaves guided from the waveguide from the TE mode into a TEM mode, and a coaxial waveguide that propagates the microwaves from the conversion port toward the chamber and converts a remaining TE mode component into the TEM mode during the propagation; a planar antenna including a plurality of slots that radiate the microwaves guided to the coaxial waveguide toward the chamber; a microwave transmitting plate made of a dielectric material that constitutes a top wall of the chamber and transmits the microwaves radiated from the plurality of slots of the planar antenna to the chamber; a gas supply mechanism that supplies a gas into the chamber; and an exhaust mechanism that exhausts an atmosphere in the chamber. A length of the coaxial waveguide is equal to or longer than a wavelength of the microwaves generated from the microwave generator.

The microwave plasma source and the microwave plasma processing apparatus may further include a stub member that corrects an electric field uniformity in a circumferential direction of the microwaves guided from the mode converter to the planar antenna. In addition, the microwave plasma source and the microwave plasma processing apparatus may further include a slow-wave member made of a dielectric material provided on an upper surface of the planar antenna. Further, a frequency of the microwaves may be 2.45 GHz.

In the microwave plasma processing apparatus, the microwave plasma processing may be a processing of supplying a film forming gas from the gas supply mechanism into the chamber and forming a predetermined film on the workpiece by plasma CVD. Specifically, the film forming gas supplied from the gas supply mechanism may be a silicon source gas, a nitrogen-containing gas, or a carbon-containing gas, and a silicon nitride film or a silicon nitride carbide film may be formed on the workpiece.

According to the present disclosure, when the length of the coaxial waveguide is set to be equal to or more than the wavelength of the microwaves, it is possible to enhance the electric field uniformity of the microwaves and improve the uniformity of the plasma processing in the plane of the workpiece.

Hereinafter, exemplary embodiments of the present disclosure will be described in detail with reference to the drawings.

<Configuration of Microwave Plasma Processing Apparatus>

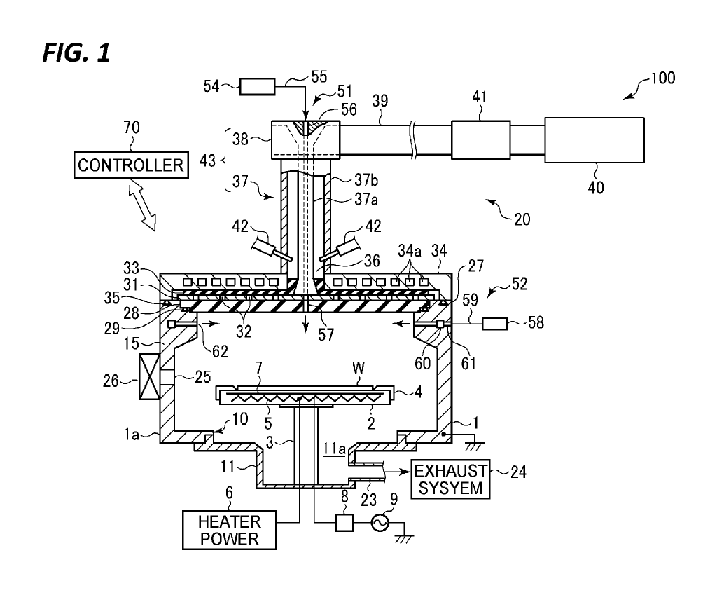

FIG. 1 is a cross-sectional view illustrating a schematic configuration of a microwave plasma processing apparatus according to an exemplary embodiment of the present disclosure. The microwave plasma processing apparatus of FIG. 1 is an RLSA (registered trademark) microwave plasma processing apparatus, and is configured as a film forming apparatus that forms, for example, a silicon nitride film.

As illustrated in FIG. 1, the microwave plasma processing apparatus 100 includes a substantially cylindrical chamber 1 which is airtightly configured and grounded. A circular opening 10 is formed in a substantially central portion of a bottom wall 1a of the chamber 1, and an exhaust chamber 11 is provided in the bottom wall 1a to communicate with the opening 10 and protrude downward.

A susceptor 2 made of ceramics (e.g., AlN) is provided in the chamber 1 to horizontally support a workpiece, for example, a semiconductor wafer (hereinafter referred to as a “wafer”) W. The susceptor 2 is supported by a cylindrical support member 3 made of ceramics (e.g., AlN) that extends upward from the center of the bottom of the exhaust chamber 11. A guide ring 4 is provided on the outer edge portion of the susceptor 2 to guide the wafer W. Further, a resistance heating type heater 5 is embedded in the susceptor 2. The heater 5 heats the susceptor 2 by supplying power from the heater power supply 6 to heat the wafer W. Further, an electrode 7 is embedded in the susceptor 2. The electrode 7 is connected with a high frequency power supply 9 for bias application via a matcher 8.

Wafer lift pins (not illustrated) for supporting and lifting the wafer W are provided in the susceptor 2 so as to protrude and retract from the surface of the susceptor 2.

An exhaust pipe 23 is connected to a lateral side of the exhaust chamber 11, and an exhaust mechanism 24 including, for example, a vacuum pump or an automatic pressure control valve is connected to the exhaust pipe 23. The vacuum pump of the exhaust mechanism 24 is operated such that the gas in the chamber 1 is uniformly discharged into a space 11a of the exhaust chamber 11 and exhausted through the exhaust pipe 23, and the inside of the chamber 1 is controlled to a predetermined degree of vacuum by the automatic pressure control valve.

The side wall of the chamber 1 is provided with a carry-in/out port 25 that carries a wafer W into/out of a conveyance chamber (not illustrated) adjacent to the plasma processing apparatus 100, and a gate valve 26 that opens and closes the carry-in/out port 25.

The upper portion of the chamber 1 is configured as an opening portion, and the peripheral portion of the opening portion is configured as a ring-shaped support 27. A microwave plasma source 20 is provided on the support 27 to form microwave plasma in the chamber 1.

The microwave plasma source 20 includes a disc-shaped microwave-transmitting plate 28 made of a dielectric material such as, for example, ceramics (e.g., quartz or Al₂O₃), a planar antenna 31, a slow-wave member 33, a mode converter 43, a waveguide 39, and a microwave generator 40.

The microwave-transmitting plate 28 is airtightly provided in the support 27 through a sealing member 29. Accordingly, the inside of the processing container 1 is airtightly maintained.

The planar antenna 31 has a disc shape corresponding to the microwave-transmitting plate 28, and is provided so as to be in close contact with the microwave-transmitting plate 28. The planar antenna 31 is locked to the upper end of the side wall of the chamber 1. The planar antenna 31 is constituted with a disc made of a conductive material.

For example, the planar antenna 31 is formed of a copper or aluminum plate whose surface is silver- or gold-plated, and has a configuration in which a plurality of slots 32 for radiating microwaves are formed so as to penetrate therethrough in a predetermined pattern. The pattern of the slots 32 is appropriately set such that microwaves are evenly radiated. For example, an exemplary pattern may be configured such that two slots 32 arranged in a T shape are paired, and a plurality of the pairs of slots 32 are arranged concentrically. The length and arrangement interval of the slots 32 are determined depending on the effective wavelength (λg) of the microwaves. For example, the slots 32 are arranged such that the interval thereof is λg/4, λg/2, or λg. The slots 32 may have other shapes such as, for example, a circular shape or an arc shape. Further, the arrangement form of the slots 32 is not particularly limited, and the slots 32 may be arranged in, for example, a spiral shape or a radial shape besides the concentric shape.

The slow-wave member 33 is provided in close contact with the upper surface of the slot plate 31. The slow-wave member 33 is made of a dielectric material having a dielectric constant larger than that of vacuum, for example, a resin such as quartz, ceramics (Al₂O₃), polytetrafluoroethylene, or polyimide. The slow-wave member 33 has a function of making the wavelength of the microwaves shorter than that in the vacuum to reduce the size of the planar antenna 31.

The thicknesses of the microwave-transmitting plate 28 and the slow-wave member 33 are adjusted such that the equivalent circuit formed by the slow-wave plate 33, the planar antenna 31, the microwave-transmitting plate 28, and the plasma satisfies the resonance condition. The phase of the microwaves may be adjusted by adjusting the thickness of the slow-wave member 33. Thus, when the thickness is adjusted such that the joint portion of the planar antenna 31 becomes an “antinode” of the standing waves, reflection of the microwaves is minimized, and radiation energy of the microwaves is maximized. Further, when the slow-wave plate 33 and the microwave-transmitting plate 28 are made of the same material, interface reflection of the microwaves may be suppressed.

The planar antenna 31 and the microwave-transmitting plate 28, and the slow-wave member 33 and the planar antenna 31 may be spaced apart from each other.

A shield cover 34 made of a metal material (e.g., aluminum, stainless steel, or copper) is provided on the upper surface of the chamber 1 to cover the planar antenna 31 and the slow-wave member 33. The upper surface of the chamber 1 and the shield cover 34 are sealed by a seal member 35. The shield cover 34 includes a cooling water flow path 34a formed therein, so that cooling water flows therethrough to cool the shield cover 34, the slow-wave member 33, the planar antenna 31, and the microwave-transmitting plate 28. The shield cover 34 is grounded.

The mode converter 43 includes a coaxial waveguide 37 and a conversion port 38. The coaxial waveguide 37 is inserted from the upper side of the opening 36 formed in the center of the upper wall of the shield cover 34. In the coaxial waveguide 37, a hollow rod-like inner conductor 37a and a cylindrical outer conductor 37b are concentrically arranged. The lower end of the inner conductor 37a is connected to the planar antenna 31. The coaxial waveguide 37 extends upward. The conversion port 38 is connected to the upper end of the coaxial waveguide 37. The conversion port 38 is connected with one end of the rectangular waveguide 39 which extends horizontally. The microwave generator 40 is connected to the other end of the waveguide 39. A matching circuit 41 is interposed in the waveguide 39.

The microwave generator 40 generates microwaves with, for example, a frequency of 2.45 GHz. The generated microwaves are propagated to the waveguide 39 in the TE mode. Then, the vibration mode of the microwaves is converted from the TE mode to the TEM mode at the conversion port 38. While being propagated through the coaxial waveguide 37, the TE mode component remaining in the TEM mode is also converted into the TEM mode and guided to the planar antenna. Various frequencies such as, for example, 8.35 GHz, 1.98 GHz, 860 MHz, or 915 MHz may be used as the frequency of the microwaves.

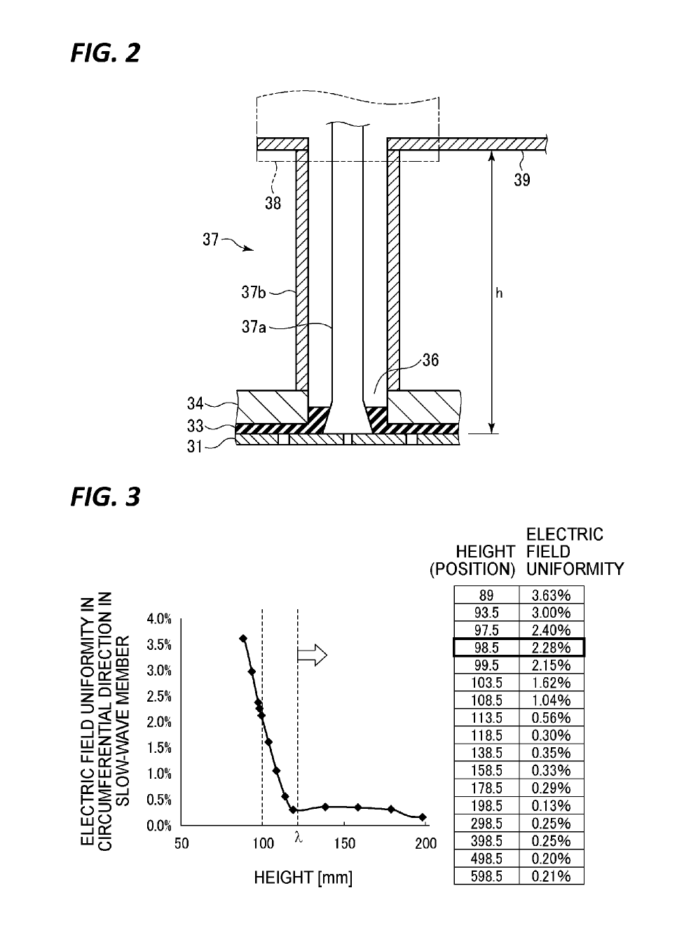

As illustrated in FIG. 2, a height (length) h of the coaxial waveguide 37 is equal to or longer than a wavelength λ of the microwaves. For example, when the frequency is 2.45 GHz, the height h of the coaxial waveguide 37 is equal to or longer than 122.4 mm which is the length of one wavelength. The height h of the coaxial waveguide 37 is the length from the bottom surface of the slow-wave member 33, which is the lower end of the inner conductor 37a, to the upper end where the outer conductor 37b comes in contact with the waveguide 39 in the mode converter 38.

The microwave plasma source 20 includes a plurality of stub members 42 provided in the circumferential direction in the lower portion of the coaxial waveguide 37 and capable of extending from the outer conductor 37b toward the inner conductor 37a. The stub member 42 has a function of adjusting the propagation of the microwaves in the circumferential direction by adjusting the distance between the tip end of the tub member 42 and the inner conductor 37a.

The microwave plasma processing apparatus 100 further includes a first gas supply mechanism 51 that supplies a gas into the chamber 1 through the coaxial waveguide 37 and the microwave-transmitting plate 28, and a second gas supply mechanism 52 that supplies a gas into the chamber 1 through the side wall of the chamber 1.

The first gas supply mechanism 51 includes a first gas source 54, a pipe 55 connected from the first gas source 54 to the upper end of the inner conductor 37a in the conversion port 38, a gas flow path 56 connected with the pipe 55 and penetrating through the inner conductor 37a in the axial direction, and a gas discharge port 57 penetrating the microwave-transmitting plate 28 so as to communicate with the gas flow path 56.

The second gas supply mechanism 52 includes a second gas source 58, a pipe 59 extending from the second gas source 58, a first buffer chamber 60 provided annularly along the side wall of the chamber 1, a gas flow path 61 connecting the pipe 59 and the first buffer chamber 60 to each other, and a plurality of gas ejection ports 62 provided horizontally to face the inside of the chamber 1 at regular intervals from the first buffer chamber 60.

The gas supply mechanisms 51 and 52 are configured to supply appropriate gases according to the plasma processing. For example, a noble gas (e.g., Ar gas), which is a plasma generation gas, is supplied from the first gas supply mechanism 51 to the vicinity of a microwave radiation region, and a cleaning gas or a film forming gas is supplied from the second gas supply mechanism 52 to the entire chamber 1. For example, in the case of forming a silicon nitride film (SiN film) by plasma CVD, a Si source gas (e.g., monosilane (SiH₄) or disilane (Si₂H₆)) and a nitrogen-containing gas (e.g., N₂ gas or ammonia (NH₃)) are used as film forming gases. Further, in the case of forming a silicon nitride carbide (SiCN film), a carbon-containing gas (e.g., ethane (C₂H₆)) is used in addition to the above-mentioned gases.

The plasma processing apparatus 100 includes a controller 70. The controller 70 includes a main controller having a CPU (computer) that controls the respective components of the microwave plasma processing apparatus 100, for example, the microwave generator 40, the heater power source 6, the high-frequency power source 9, the exhaust mechanism 24, and valves or mass flow controllers of the gas supply mechanisms 51 and 52, an input device (e.g., a keyboard and a mouse), an output device (e.g., a printer), a display device (e.g., a display), and a storage device (e.g., a storage medium). The storage device stores parameters of various processings executed by the microwave plasma processing apparatus 100, and includes a storage medium that stores a program for controlling a processing executed in the microwave plasma processing apparatus 100, that is, a processing recipe. The main controller calls up a predetermined processing recipe stored in the storage medium, and controls the microwave plasma processing apparatus 100 to perform a predetermined processing based on the processing recipe.

<Operation of Microwave Plasma Processing Apparatus>

Next, descriptions will be made on the operation of the microwave plasma processing apparatus 100 configured as described above.

First, the gate valve 26 is opened, and a wafer W as a processing target substrate is carried into the chamber 1 from the carry-in/out port 25 and placed on the susceptor 2.

Then, the interior of the chamber 1 is evacuated to a predetermined pressure. While a predetermined gas is generated into the chamber 1 from an appropriate one of the first and second gas supply mechanisms 51 and 52, microwaves are introduced to generate plasma in the chamber 1. For example, microwaves with a predetermined power are generated from the microwave generator 40 while a plasma generation gas (e.g., Ar gas) is introduced from the first gas supply mechanism 51, and the generated microwaves are propagated to the waveguide 39 in the TE mode, converted into the TEM mode by the conversion port 38 constituting the mode converter 43, and propagated to the coaxial waveguide 37 which also constitutes the mode converter 43. Thus, the remaining TE mode components are also converted into the TEM mode and radiated into the chamber 1 via the slow-wave member 33, the slots 32 of the planar antenna 31, and the microwave-transmitting plate 28.

The microwaves spread as a surface wave only in a region directly under the microwave-transmitting plate 28, so that surface wave plasma is generated. Then, the plasma is dispersed downward and becomes plasma of high electron density and low electron temperature in the region where the wafer W is arranged.

A film forming gas is supplied from the second gas supply mechanism 52 toward the wafer W, and excited by the surface wave plasma, so that a predetermined film is formed on the wafer by plasma CVD. For example, a Si source gas (e.g., monosilane (SiH₄) or disilane (Si₂H₆)) and a nitrogen-containing gas (e.g., N₂ gas or ammonia (NH₃)) are used as a film forming gas to form a SiN film. Further, a SiCN film is formed by further using a carbon-containing gas (e.g., ethane (C₂H₆)) as a film forming gas.

At this time, the propagation of the microwaves is adjusted in the circumferential direction by the stub member 42 to correct the non-uniformity of the electric field, thereby improving the in-plane uniformity of the plasma processing.

However, although the non-uniformity of the electric field in the circumferential direction may be corrected to some extent by the stub member 42, it is difficult to obtain a desired electric field uniformity only with the stub member 42.

Therefore, in the present exemplary embodiment, attention was paid to the height (length) of the coaxial waveguide 37.

As a result, the microwaves transmitted in the TE mode from the waveguide 39 having the rectangular cross section are converted into the TEM mode at the conversion port 38, are propagated through the coaxial waveguide 37, reach the slow-wave member 33, and are radiated from the slots of the planar antenna 31. However, it was found that the electric field uniformity in the circumferential direction of the transmitted microwaves at this time is related to the length of the coaxial waveguide 37.

This will be described in detail.

In the RLSA (registered trademark) microwave plasma processing apparatus, the microwave supply unit is manufactured by an antenna manufacturer, and its design is also made by an antenna manufacturer. For example, in an apparatus having a frequency of 2.45 GHz, the height (length) of the coaxial waveguide was designed to be 98.5 mm.

However, in the case of the microwave plasma processing apparatus, the ordinary antenna design as described above is not necessarily optimal due to, for example, the influence of reflection of the microwaves by plasma. Further, the conversion of the vibration mode of the microwaves is not completely performed at the conversion port 38, and the converted mode is stabilized as it is transmitted through the coaxial waveguide 37.

Therefore, as a result of a verification of the relationship between the height (length) h of the coaxial waveguide 37 and the electric field uniformity under a hypothesis that the non-uniformity of the electric field is not optimized for the height h of the coaxial waveguide 37, it has been found that when the height h of the coaxial waveguide 37 is equal to or longer than the wavelength λ of the microwaves, it is stably converted into the TEM so that a sufficient electric field uniformity may be obtained.

Hereinafter, simulation results used for the verification will be described.

Here, the relation between the height h of the coaxial waveguide 37 (the upper end position of the coaxial waveguide) and the electric field uniformity in the circumferential direction in the slow-wave member was obtained by electromagnetic field simulation. The results are illustrated in FIG. 3.

As illustrated in FIG. 3, it has been confirmed that when the height h of the coaxial waveguide 37 is 98.5 mm as in the related art, the electric field uniformity is 2.28%, whereas when the height h of the coaxial waveguide 37 is increased, the electric field uniformity tends to increase, and when the height h of the coaxial waveguide 37 becomes equal to or larger than the wavelength λ of the microwaves, the electric field uniformity is stabilized at a value of about 0.3% or lower.

From this confirmation, it has been verified that when the height h of the coaxial waveguide 37 is equal to or larger than the wavelength λ of the microwaves, the electric field uniformity in the circumferential direction in the slow-wave material becomes stable and satisfactory. This may be because when the height h of the coaxial waveguide 37 is 98.5 mm as in the related art, the TE mode is not sufficiently converted into the TEM mode and the electric field becomes unstable, but as the height h of the coaxial waveguide 37 increases, the degree of conversion into the TEM mode increases, and when the height h of the coaxial waveguide 37 becomes equal to or larger than the wavelength λ of the microwaves, the TEM mode is substantially stably formed.

The above-described simulation results relate to the case where the frequency of the microwaves is 2.45 GHz. However, the electric field uniformity may be stably enhanced at the other frequencies as well when the height of the coaxial waveguide 37 is equal to or larger than the wavelength λ of the microwaves.

Therefore, the electric field uniformity in the circumferential direction may be enhanced by setting the height h of the coaxial waveguide 37 to be equal to or larger than the wavelength λ of the microwaves. Thus, it is possible to perform a microwave plasma processing with high plasma uniformity in the plane of the wafer which is a processing target substrate. Therefore, it is possible to enhance the uniformity of the film thickness when forming the film by plasma CVD.

Further, after the height h of the coaxial waveguide 37 is set to be equal to or larger than the wavelength λ of the microwaves, the stub member 42 is adjusted to correct the non-uniformity of the electric field, thereby further increasing the electric field uniformity.

In this manner, after a predetermined film is formed by plasma CVD using microwave plasma, the inside of the chamber 1 is purged, and the processed wafer W is carried out therefrom.

After the microwave plasma processing is performed on a predetermined number of wafers, for example, an appropriate cleaning gas is supplied into the chamber 1 from the second gas supply mechanism to clean the inside of the chamber 1.

<Other Applications>

For example, in the exemplary embodiment, the plasma CVD has been described as an example of the microwave plasma processing, but the present disclosure is not limited thereto. The present disclosure may also be applied to other plasma processing such as, for example, plasma etching, plasma oxidation processing, or plasma nitriding processing.

Further, in the exemplary embodiment, descriptions have been made on the case of providing a first gas supply mechanism for supplying a gas through the coaxial waveguide and the microwave-transmitting plate, and a second gas supply mechanism for supplying a gas through the side wall of the chamber. However, the number of gas supply mechanisms may be one, or two or more, and the gas introduction part is not limited to the exemplary embodiment. As a specific example, it has been described that a plasma generation gas is supplied to the vicinity of the microwave radiation region by the first gas supply mechanism, and a film formation gas is supplied to the vicinity of the wafer by the second gas supply mechanism. However, the present disclosure is not limited thereto, and various gas supply forms may be adopted depending on the applications, such as irradiation of the microwave radiation region from the top wall of the chamber with a gas which is desired to promote dissociation by plasma among film formation gases. The plasma generation gas (e.g., Ar gas) is not indispensable.

Further, in the exemplary embodiment, descriptions have been made on the case of using a semiconductor wafer as a processing target substrate. However, the processing target substrate is not limited to the semiconductor wafer, and may be another workpiece such as, for example, a glass substrate or a ceramic substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A microwave plasma source that generates microwave plasma by radiating microwaves into a chamber in a microwave plasma processing apparatus for performing a plasma processing in the chamber, the microwave plasma source comprising:
a microwave generator that generates microwaves;
a waveguide that propagates the microwaves generated by the microwave generator in a TE mode;
a microwave converter including a conversion port that converts a vibration mode of the microwaves guided from the waveguide from the TE mode into a TEM mode, and a coaxial waveguide that propagates the microwaves from the conversion port toward the chamber and converts a remaining TE mode component into the TEM mode during the propagation;
a planar antenna including a plurality of slots that radiate the microwaves guided to the coaxial waveguide toward the chamber; and
a microwave transmitting plate made of a dielectric material that transmits the microwaves radiated from the plurality of slots of the planar antenna to the chamber,
wherein a length of the coaxial waveguide is equal to or longer than a wavelength of the microwaves generated from the microwave generator.

2. The microwave plasma source of claim 1, further comprising:
a stub member that corrects an electric field uniformity in a circumferential direction of the microwaves guided from the mode converter to the planar antenna.

3. The microwave plasma source of claim 1, further comprising:
a slow-wave member made of a dielectric material provided on an upper surface of the planar antenna.

4. The microwave plasma source of claim 1, wherein a frequency of the microwaves is 2.45 GHz.

5. A microwave plasma processing apparatus comprising:
a chamber in which a workpiece is accommodated;
a microwave generator that generates microwaves;
a waveguide that propagates the microwaves generated by the microwave generator in a TE mode;
a microwave converter including a conversion port that converts a vibration mode of the microwaves guided from the waveguide from the TE mode into a TEM mode, and a coaxial waveguide that propagates the microwaves from the conversion port toward the chamber and converts a remaining TE mode component into the TEM mode during the propagation;
a planar antenna including a plurality of slots that radiate the microwaves guided to the coaxial waveguide toward the chamber;
a microwave transmitting plate made of a dielectric material that constitutes a top wall of the chamber and transmits the microwaves radiated from the plurality of slots of the planar antenna to the chamber;
a gas supply mechanism that supplies a gas into the chamber; and
an exhaust mechanism that exhausts an atmosphere in the chamber,
wherein a length of the coaxial waveguide is equal to or longer than a wavelength of the microwaves generated from the microwave generator.

6. The microwave plasma processing apparatus of claim 5, further comprising:
a stub member that corrects an electric field uniformity in a circumferential direction of the microwaves guided from the mode converter to the planar antenna.

7. The microwave plasma processing apparatus of claim 5, further comprising:
a slow-wave member made of a dielectric material provided on an upper surface of the planar antenna.

8. The microwave plasma processing apparatus of claim 5, wherein a frequency of the microwaves is 2.45 GHz.

9. The microwave plasma processing apparatus of claim 5, wherein the microwave plasma processing is a processing of supplying a film forming gas from the gas supply mechanism into the chamber and forming a predetermined film on the workpiece by plasma CVD.

10. The microwave plasma processing apparatus of claim 9, wherein the film forming gas supplied from the gas supply mechanism is a silicon source gas, a nitrogen-containing gas, or a carbon-containing gas, and a silicon nitride film or a silicon nitride carbide film is formed on the workpiece.
